(19) United States
(12) Patent Application Publication
(10) Pub. No.: US 2026/0223552 A1
(43) Pub. Date: Jul. 30, 2026

(54) DISPLAY DEVICE INCLUDING INCLINED INSULATING LAYER, ELECTRONIC DEVICE, AND METHOD FOR MANUFACTURING A DISPLAY DEVICE

(71) Applicant: SAMSUNG DISPLAY CO., LTD., YONGIN-SI (KR)

(72) Inventors: HANBIT KIM, Yongin-si (KR); MEEJAE KANG, Yongin-si (KR); HYENA KWAK, Yongin-si (KR); CHANYEOB SEOL, Yongin-si (KR); SANGGUN CHOI, Yongin-si (KR); Taehyun Hong, Yongin-si (KR)

(21) Appl. No.: 19/309,820

(22) Filed: Aug. 26, 2025

(30) Foreign Application Priority Data
Jan. 21, 2025 (KR) 10-2025-0008468

(51) Int. Cl. H10K 59/124; H10K 59/12

(52) U.S. Cl. CPC H10K 59/124; H10K 59/1201

(57) ABSTRACT

A display device includes a substrate having a light-emitting region defined therein, a transistor, an inclined insulating layer, a conductive layer, a flat layer, a pixel electrode, a light-emitting layer, and a common electrode. The transistor is disposed on the substrate and includes a circuit electrode. A first opening is defined in a first inclined surface of the inclined insulating layer, and a second opening is defined in a second inclined surface thereof. The conductive layer is disposed on the inclined insulating layer and the circuit electrode and is electrically connected to the circuit electrode through the first opening. The pixel electrode is disposed on the flat layer and the conductive layer and is in direct contact with the flat layer and the conductive layer. The second opening has a larger area than the first opening and the light-emitting region. The flat layer covers the light-emitting region.

### CROSS-REFERENCE TO RELATED APPLICATIONS

This application claims priority under 35 U.S.C. § 119 to Korean Patent Application No. 10-2025-0008468, filed on Jan. 21, 2025, the content of which is incorporated by reference herein in its entirety.

### TECHNICAL FIELD

The present disclosure relates to a display device and, more specifically, to a display device including an inclined insulating layer, an electronic device, and a method for manufacturing a display device.

### DISCUSSION OF THE RELATED ART

An organic light-emitting diode (OLED) display device is capable of generating its own light without the use of a separate light source, such as a backlight device. This stands in contrast to liquid crystal display (LCD) devices. For this reason, organic light-emitting display devices may be thinner and lighter than comparable liquid crystal display devices. Moreover, organic light-emitting display devices exhibit superior characteristics, including low power consumption, high luminance, and fast response speed.

### SUMMARY

A display device includes a substrate, a transistor, an inclined insulating layer, a conductive layer, a flat layer, a pixel electrode, a light-emitting layer, and a common electrode.

The substrate includes a light-emitting region. The transistor is disposed on the substrate and includes a circuit electrode. The inclined insulating layer is disposed on the transistor. The inclined insulating layer includes a first inclined surface in which a first opening is defined and a second inclined surface in which a second opening is defined.

The conductive layer is disposed on the inclined insulating layer and the circuit electrode and directly contacts the circuit electrode. The conductive layer is electrically connected to the circuit electrode through the first opening.

The flat layer is disposed on the conductive layer. The pixel electrode is disposed on the flat layer and the conductive layer and directly contacts the flat layer and the conductive layer. The light-emitting layer is disposed on the pixel electrode. The common electrode is disposed on the light-emitting layer.

The first opening, the second opening, and the light-emitting region overlap each other in the plan view. The second opening has a larger area than each of the first opening and the light-emitting region. The flat layer covers the light-emitting region in a plan view.

The pixel electrode may cover the flat layer. The pixel electrode may extend in parallel to a plane defined by a first direction and a second direction intersecting the first direction.

The conductive layer may include a first contact portion making contact with the pixel electrode. The first contact portion might not overlap the light-emitting region.

The conductive layer may further include a second contact portion, which is spaced apart from the first contact portion and makes contact with the pixel electrode. The second contact portion might not overlap the light-emitting region.

The first contact portion and the second contact portion may face each other with the flat layer interposed therebetween.

The conductive layer may include first to third flat portions extending in parallel with the substrate. The first flat portion may be in contact with the circuit electrode. The second flat portion may be in contact with both the inclined insulating layer and the flat layer. The third flat portion may be in contact with both the inclined insulating layer and the pixel electrode.

A first distance between the first flat portion and the substrate may be smaller than a second distance between the second flat portion and the substrate. A third distance between the third flat portion and the substrate may be greater than the second distance.

An upper surface of the third flat portion and an upper surface of the flat layer may have substantially the same height with respect to the substrate.

The conductive layer may be a single uninterrupted structure.

One side of the conductive layer and one side of the pixel electrode may overlap each other in the plan view.

One side of the conductive layer and one side of the pixel electrode may be spaced apart from each other.

The inclined insulating layer may include at least one inorganic layer and at least one organic layer.

The inclined insulating layer may further include a third inclined surface in which a third opening is defined. The third opening and the first opening may overlap each other in the plan view. The third opening may have a larger area than the first opening and a smaller area than the second opening.

The pixel electrode may have a symmetrical shape with respect to a central axis extending in the first direction through the pixel in a the plan view.

A method for manufacturing a display device includes preparing a substrate, forming a circuit layer, forming an inclined insulating layer, forming a preliminary conductive layer, forming a flat layer, forming a conductive layer and a pixel electrode, forming a light-emitting layer, and forming a common electrode.

The substrate includes a light-emitting region defined therein. The transistor includes a circuit electrode. The inclined insulating layer includes a first inclined surface in which a first opening is defined and a second inclined surface in which a second opening is defined.

In the step of forming a circuit layer, a circuit layer including a transistor is formed on the substrate.

In the step of forming an inclined insulating layer, an inclined insulating layer is formed on the circuit layer.

In the step of forming a preliminary conductive layer, a preliminary conductive layer is formed on the inclined insulating layer.

In the step of forming a flat layer, a flat layer is formed on the preliminary conductive layer.

In the step of forming a conductive layer and a pixel electrode, a conductive layer and a pixel electrode are formed on the flat layer.

In the step of forming a light-emitting layer, a light-emitting layer is formed on the pixel electrode.

In the step of forming a common electrode, a common electrode is formed on the light-emitting layer.

The pixel electrode and the conductive layer are electrically connected to each other. The conductive layer and the transistor are electrically connected with each other through the first opening. The second opening has a larger area than each of the first opening and the light-emitting region. The flat layer covers the light-emitting region.

Forming the flat layer may include patterning a second preliminary flat layer on the conductive layer overlapping the light-emitting region and planarizing the second preliminary flat layer to form the flat layer.

The step of forming a conductive layer and a pixel electrode may include forming a preliminary pixel electrode on the flat layer and the conductive layer and etching the preliminary pixel electrode and the preliminary conductive layer.

The step of etching both the preliminary pixel electrode and the preliminary conductive layer may be performed in a single process.

A display device includes a substrate, a transistor, an inclined insulating layer, a conductive layer, a flat layer, a pixel electrode, a light-emitting layer, and a common electrode.

The substrate includes a light-emitting region defined therein. The transistor is disposed on the substrate and includes a circuit electrode. The inclined insulating layer is disposed on the transistor. The conductive layer is disposed on the inclined insulating layer and includes first to third flat portions extending in parallel with the substrate. The flat layer is disposed on the conductive layer. The pixel electrode is disposed on both the flat layer and the conductive layer and directly contacts both the flat layer and the conductive layer. The light-emitting layer is disposed on the pixel electrode. The common electrode is disposed on the light-emitting layer.

The first flat portion is in contact with the circuit electrode. The second flat portion is in direct contact with each of the inclined insulating layer and the flat layer. The third flat portion is in direct contact with each of the inclined insulating layer and the pixel electrode. The flat layer covers the light-emitting region in the plan view.

A first distance between the first flat portion and the substrate may be smaller than a second distance between the second flat portion and the substrate. A third distance between the third flat portion and the substrate may be greater than the second distance.

The third flat portion might not overlap the light-emitting region in a plan view.

The inclined insulating layer may include a first inclined surface in which a first opening is defined and a second inclined surface in which a second opening is defined. The conductive layer may be electrically connected to the circuit electrode through the first opening. The second opening may have a larger area than the first opening and the light-emitting region. The conductive layer may be a single uninterrupted structure.

An electronic device includes a substrate, a transistor, an inclined insulating layer, a conductive layer, a flat layer, a pixel electrode, a light-emitting layer, and a common electrode.

The substrate includes a light-emitting region defined therein. The transistor is disposed on the substrate and includes circuit electrodes. The inclined insulating layer is disposed on the transistor. The inclined insulating layer includes a first inclined surface in which a first opening is defined and a second inclined surface in which a second opening is defined. The conductive layer is disposed on the inclined insulating layer and the circuit electrode and directly contacts the circuit electrode. The conductive layer is electrically connected to the circuit electrode through the first opening. The flat layer is disposed on the conductive layer. The pixel electrode is disposed on the flat layer and the conductive layer and directly contacts the flat layer and the conductive layer. The light-emitting layer is disposed on the pixel electrode. The common electrode is disposed on the light-emitting layer.

The first opening, the second opening, and the light-emitting region overlap each other in a plan view. The second opening has a larger area than each of the first opening and the light-emitting region. The flat layer covers the light-emitting region in the plan view.

The electronic device may further include a processor configured to control the display device, a memory storing data for operating the display device or the processor stored therein, and a power conversion module configured for generating or supplying power.

### BRIEF DESCRIPTION OF THE DRAWINGS

These and/or other features will become apparent and more readily appreciated from the following description of the embodiments, taken in conjunction with the accompanying drawings in which:

FIG. 1 is a plan view illustrating a display device according to an embodiment of the present disclosure;

FIG. 2 is a cross-sectional view illustrating a part of the display device according to an embodiment;

FIG. 3 is an enlarged cross-sectional view of region BB of FIG. 2;

FIG. 4 is a cross-sectional view illustrating a part of a display device of a comparative example;

FIG. 5 is a cross-sectional view illustrating a part of a display device according to an embodiment;

FIG. 6 is a plan view illustrating a certain pixel according to an embodiment;

FIG. 7 is a cross-sectional view illustrating a part of a display device according to an embodiment;

FIG. 8 is a plan view illustrating a pixel according to an embodiment;

FIG. 9 is a plan view illustrating a pixel according to an embodiment;

FIG. 10 is a plan view illustrating a pixel according to an embodiment;

FIG. 11 is a cross-sectional view illustrating a part of the display device according to an embodiment;

FIG. 12 is a cross-sectional view illustrating a part of the display device according to an embodiment;

FIG. 13 is a plan view illustrating a part of a display device of a comparative example;

FIG. 14 is a plan view illustrating a part of a display device according to an embodiment;

FIG. 15 is a flowchart illustrating a method for manufacturing a display device according to an embodiment;

FIGS. 16A to 16I are cross-sectional views schematically illustrating respective manufacturing steps of a display device;

FIG. 17 is a block diagram of an electronic device according to an embodiment; and

FIGS. 18 to 20 are schematic views illustrating various examples of electronic devices according to embodiments.

### DETAILED DESCRIPTION

References will now be made in detail to certain embodiments, of which examples are illustrated in the accompanying drawings, where like reference numerals may refer to like elements throughout the specification and the figures. The embodiments may have a variety of forms and permutations, but the present disclosure is not necessarily limited to the described embodiments. Rather, the present disclosure shall be construed to encompass all forms, permutations, equivalents and substitutes covered by the technical ideas and scope of the present disclosure. Accordingly, the embodiments are described below, by referring to the figures, to explain features of the present disclosure.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly but also as possibly having another element interposed therebetween. If one element is described to be “directly disposed on,” “directly placed on,” “directly arranged on,” “directly connected to,” or “directly coupled to” another element, it shall be construed that there is no other element interposed therebetween.

Like or identical reference numerals may refer to like or identical elements. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Terms such as “first” and “second” may be used in describing various elements, but the above elements shall not necessarily be restricted to the above terms. The above terms may be used to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

In the present specification, when a particular process sequence may be implemented differently, the described sequence of processes may be performed in a different order. For example, two sequentially described processes may be performed substantially simultaneously, or the order of description may be reversed.

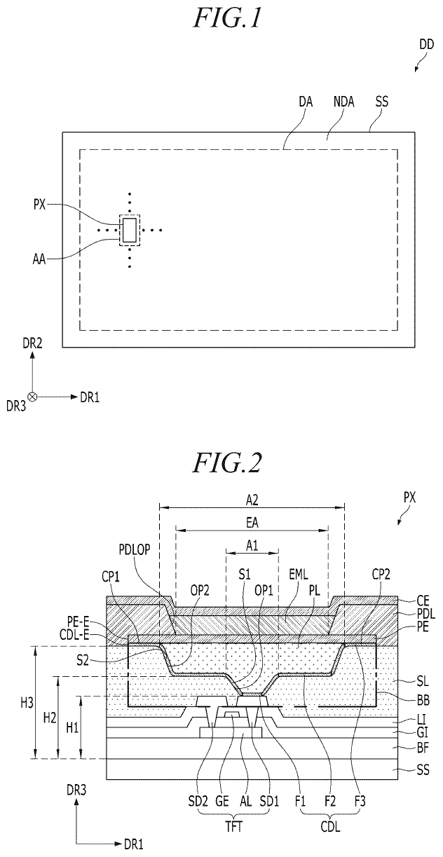

First through third directions DR1, DR2, DR3 may be defined. The first direction DR1 and the second direction DR2 may be directions defined in the plane of the display device DD shown in FIG. 1 and may intersect each other. The third direction DR3 may be the thickness direction of the display device DD, as defined in FIG. 2.

The expression “in a plan view” in this specification may refer to a view along the third direction DR3, i.e., a direction viewing from the top of the structure toward the bottom. Additionally, in this specification, any description based on a particular direction may include not only the direction shown in the drawing but also the concept of an opposite direction to the depicted direction.

Embodiments of the present disclosure relate to a display device, for example an organic light-emitting diode (OLED) display, designed to enhance performance and reliability through a novel pixel electrode structure. An improved architectural arrangement may be used where a conductive layer connects a pixel electrode to a circuit electrode of a transistor through a multi-angled insulating layer. This insulating layer includes at least two distinct inclined surfaces, each defining separate openings (e.g., in the shape of a truncated cone) that facilitate electrical connections at different heights. The conductive layer extends across these surfaces and provides a stable electrical path from the circuit electrode to the pixel electrode, enhancing the integrity and manufacturability of the electrical interface.

A flat layer is placed directly beneath the pixel electrode. This flat layer spans the light-emitting region and serves to provide a uniform foundation for the pixel electrode, which directly contacts both the flat and conductive layers. The combination ensures that the pixel electrode sits on a consistent surface, leading to more uniform light emission. This is in contrast to designs where uneven underlying structures caused irregular emission patterns. The pixel electrode's geometry is also refined to maximize the light-emitting area by eliminating the need for a separate contact region, thus improving luminous efficiency and potentially extending the lifespan of the display.

From a manufacturing perspective, embodiments of the present disclosure enable a streamlined process wherein the conductive layer and pixel electrode can be patterned simultaneously in a single etching step. This not only reduces complexity but also ensures precise alignment between layers. The result is a thinner, more efficient display that supports high-resolution applications such as virtual reality devices, where display density and power efficiency are important. The improved contact structure and layered configuration contribute to enhanced display quality, increased panel uniformity, and better overall reliability in consumer electronics.

FIG. 1 is a plan view illustrating a display device according to an embodiment of the present disclosure. FIG. 2 is a cross-sectional view illustrating a part of the display device according to an embodiment.

Referring to FIG. 1, a display device DD, according to an embodiment may include a display area DA and a non-display area NDA positioned outside the display area DA. While FIG. 1 depicts the display area DA as having a generally rectangular shape, the present disclosure is not necessarily limited thereto. The display area DA may have various shapes such as circular, elliptical, or polygonal.

The display area DA, which serves as a region for displaying images, may have a plurality of pixels PX arranged therein. Each pixel PX may include a light-emitting diode such as an organic light-emitting diode (OLED). For example, each pixel PX may be configured to emit red, green, blue, or white light.

The display area DA may be configured to provide a predetermined image through the light emitted from the pixels PX. As described above, each pixel PX may include a light-emitting region configured to emit light in red, green, blue, or white color.

The non-display area NDA is a region where pixels PX are not arranged (a region in which the pixels PX are omitted) and may serve as a region that does not display images. A printed circuit board may be disposed in the non-display area NDA. The printed circuit board may include power supply wiring and a driving circuit unit configured to drive the pixels PX, or a terminal portion, to which a driver IC is connected.

Hereinafter, the display device DD, according to an embodiment of the present disclosure, will be described with an organic light-emitting display device as an example. However, the display device DD, according to an embodiment of the present disclosure, is not necessarily limited thereto. The display device DD may be an inorganic light-emitting display device (or inorganic EL display device) or a quantum dot light-emitting display device (QLED). For example, the light-emitting layer included in the light-emitting diode LED of the display device DD may include either an organic material or an inorganic material. Additionally, quantum dots may be located in the optical path of the light emitted from the light-emitting layer.

Thus, the display device includes a display area DA, where an array of light-emitting pixels, such as OLEDs, produce images, and a surrounding non-display area NDA that houses components like circuitry and driver connections. While the example focuses on an organic light-emitting display, the design is also applicable to inorganic or quantum dot-based display technologies.

Referring to FIG. 2, the display device DD, according to an embodiment, may include a substrate SS, a buffer layer BF, a transistor TFT, a gate insulating film GI, an interlayer insulating film LI, an inclined insulating layer SL, a conductive layer CDL, a flat layer PL, a pixel electrode PE, a light-emitting layer EML, a common electrode CE, and a pixel defining layer PDL.

It is noted that the flat layer PL may have an upper surface that is flat and the other surfaces thereof need not be flat. The flat layer PL may also be referred to herein as a supporting layer as it supports the pixel layer.

The substrate SS may be formed from various materials such as glass, metal, or plastic. In an embodiment, the substrate SS may be a flexible substrate that is capable of being flexed, stretched, and/or bent, to a noticeable extent, without cracking or otherwise sustaining damage. For example, the substrate SS may include polymer resins such as polyethersulfone (PES), polyacrylate (PAR), polyetherimide (PEI), polyethylene naphthalate (PEN), polyethylene terephthalate (PET), polyphenylene sulfide (PPS), polyarylate (PA), polyimide (PI), polycarbonate (PC), or cellulose acetate propionate (CAP).

The buffer layer BF may be configured to prevent impurity ions from diffusing on an upper surface of the substrate SS, block moisture or external air infiltration, and planarize the surface. In some embodiments, the buffer layer BF may be formed of inorganic materials such as silicon oxide, silicon nitride, silicon oxynitride, aluminum oxide, aluminum nitride, titanium oxide, or titanium nitride, or organic materials such as polyimide, polyester, or acrylic, or a laminate structure of these materials.

The transistor TFT may include an active layer AL disposed on the substrate SS, a gate electrode GE disposed on at least a portion of the active layer AL, and circuit electrodes SD1, SD2 disposed on the gate electrode GE and electrically connected with the active layer AL. One of the circuit electrodes SD1, SD2 may be a source electrode, and the other may be a drain electrode.

The active layer AL may be disposed on the buffer layer BF. Used to form the active layer AL may be an inorganic semiconductor, such as amorphous silicon or polysilicon, or an organic semiconductor. In an embodiment, the active layer AL may be formed of an oxide semiconductor, including an oxide of materials selected from group 12, 13, or 14 metals, such as zinc (Zn), indium (In), gallium (Ga), tin (Sn), cadmium (Cd), germanium (Ge), or hafnium (Hf), or a combination thereof.

The gate insulating film GI may be disposed on the buffer layer BF and may cover the active layer AL. The gate electrode GE may be disposed on the gate insulating film GI.

The interlayer insulating film LI may be disposed on the gate insulating film GI and the gate electrode GE and may cover the gate electrode GE. The circuit electrodes SD1, SD2 may be formed on the interlayer insulating film LI and may be in contact with the active layer AL through a contact hole.

The inclined insulating layer SL may be disposed on the source electrode SE, the drain electrode DE, and the interlayer insulating film LI. In an embodiment, the inclined insulating layer SL may include a first inclined surface S1, in which a first opening OP1 is defined, and a second inclined surface S2, in which a second opening OP2 is defined. A detailed description of the inclined insulating layer SL will be provided later.

The conductive layer CDL may be disposed on the circuit electrode SD1 and the inclined insulating layer SL. The conductive layer CDL may be in direct contact with the circuit electrode SD1 and the pixel electrode PE to electrically connect the circuit electrode SD1 and the pixel electrode PE. A detailed description of the conductive layer CDL will be provided later.

The flat layer PL may be disposed on the conductive layer CDL. The flat layer PL may provide a flat surface for the pixel electrode PE, which will be described later. A detailed description of the flat layer PL will be provided later.

The pixel electrode PE may be disposed on the conductive layer CDL and the flat layer PL. The pixel electrode PE may function as an anode or cathode and may be electrically connected with the transistor TFT through the conductive layer CDL. In an embodiment, the pixel electrode PE may be in direct contact with the conductive layer CDL and the flat layer PL.

The pixel electrode PE may be formed of a conductive oxide such as indium tin oxide (ITO), indium zinc oxide (IZO), zinc oxide (ZnO), indium oxide (In₂O₃), indium gallium oxide (IGO), or aluminum zinc oxide (AZO).

In an embodiment, the pixel electrode PE may include a reflective film containing silver (Ag), magnesium (Mg), aluminum (Al), platinum (Pt), palladium (Pd), gold (Au), nickel (Ni), neodymium (Nd), iridium (Ir), or chromium (Cr) or a compound thereof.

In an embodiment, the pixel electrode PE may further include a film formed of ITO, IZO, ZnO, or In₂O₃, which is disposed above and/or below the aforementioned reflective film. For example, the pixel electrode PE may have a multilayer structure of ITO/Ag/ITO.

The pixel defining layer PDL may be disposed on the pixel electrode PE and the inclined insulating layer SL and may include a pixel opening PDLOP that defines a light-emitting region EA. The pixel defining layer PDL may be configured to increase the distance between an edge of the pixel electrode PE and the common electrode CE, thereby preventing an arc from occurring between them. The pixel defining layer PDL may be formed of an organic material such as polyimide or hexamethyldisiloxane (HMDSO).

The light-emitting layer EML may include an organic material containing a fluorescent or phosphorescent material configured to emit red, green, blue, or white light. The light-emitting layer EML may be a small-molecule organic material or a polymer organic material, and functional layers such as a hole transport layer (HTL), a hole injection layer (HIL), an electron transport layer (ETL), and an electron injection layer (EIL) may be selectively further disposed above and below the light-emitting layer EML.

The common electrode CE may be a transparent electrode or a reflective electrode. Alternatively, the common electrode CE may be a transparent or semi-transparent electrode and may be formed of a metal thin film containing one or more of ytterbium (Yb), lithium (Li), calcium (Ca), lithium fluoride/calcium (LiF/Ca), lithium fluoride/aluminum (LiF/Al), aluminum (Al), silver (Ag), and magnesium (Mg), or a compound thereof. Additionally, a transparent conductive oxide (TCO) film such as ITO, IZO, ZnO, or In₂O₃ may be further disposed on the metal thin film. The common electrode CE may be disposed across both the display area DA and the non-display area NDA and may be located above the light-emitting layer EML and the pixel defining layer PDL.

According to an embodiment, the inclined insulating layer SL may include the first inclined surface S1 and the second inclined surface S2. The first inclined surface S1 may have the first opening OP1, which exposes one of the circuit electrodes SD1, SD2, defined therein. FIG. 2 illustrates an example in which the circuit electrode SD1 is exposed. The first inclined surface S1 may overlap with an edge of the circuit electrode SD1 and expose a portion of an upper surface of the circuit electrode SD1.

The second inclined surface S2 may be spaced more apart from the substrate in a third direction DR3 than the first inclined surface S1. The second inclined surface S2 may be spaced apart from the first inclined surface S1 in a first direction DR1. The second opening OP2, which covers the entire light-emitting region EA, may be defined by the second inclined surface S2.

In an embodiment, the first opening OP1 and the second opening OP2 may be connected to each other, and the second opening OP2 may be defined above the first opening OP1. In an embodiment, the second opening OP2 may have a larger width than the first opening OP1.

The inclined insulating layer SL may include an inorganic material and/or an organic material.

It is noted that openings OP1 and OP2 may each have a shape of a truncated cone peripherally defined by the respective inclined surfaces. In this way, the openings are defined by the inclined surfaces.

Thus, the display device may include a layered structure built on a flexible or rigid substrate, incorporating a transistor, insulating layers with sloped surfaces and openings, a conductive layer, a flat layer, and a pixel electrode, all arranged to support uniform and efficient light emission. These components work together to connect the pixel electrode to the transistor, define the light-emitting region, and enable the emission of light through an organic light-emitting layer beneath a common electrode.

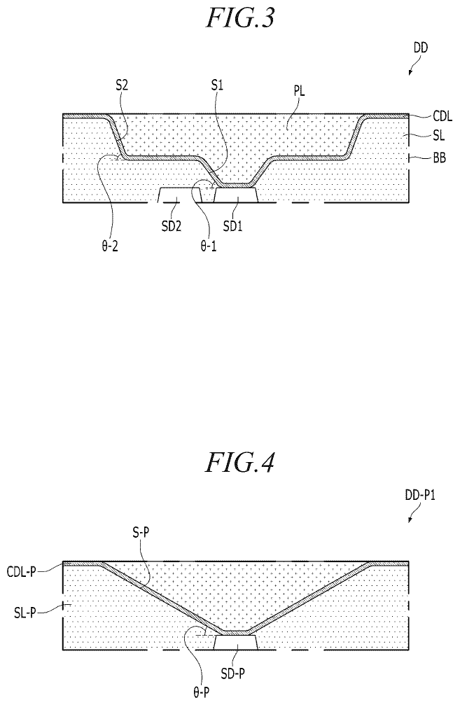

FIG. 3 is an enlarged view of region BB of FIG. 2. FIG. 4 illustrates a part of a display device of a comparative example. For convenience of description, other components may have been omitted in FIGS. 3 and 4 and to the extent that an element is not described in detail with respect to this figure, it may be understood that the element is at least similar to a corresponding element that has been described elsewhere within the present disclosure.

Referring to FIG. 3, according to an embodiment of the present disclosure, the first inclined surface S1 and the second inclined surface S2 are spaced apart in the first direction DR1, allowing the conductive layer CDL, which will be described later, to be stably formed on the inclined surfaces S1, S2.

Referring to FIG. 4, in a comparative example display device DD-P1, the inclined insulating layer SL-P has a single inclined surface S-P, and the conductive layer CDL-P extends along the inclined surface S-P at a predetermined angle θ-P. The predetermined angle θ-P is smaller than a predetermined value required for the stable formation of the conductive layer CDL-P.

In the display device DD, according to an embodiment of the present disclosure, since the inclined insulating layer SL has the first inclined surface S1 and the second inclined surface S2, which are spaced apart from each other, the conductive layer CDL may extend at a first angle θ-1 on the first inclined surface S1 and at a second angle θ-2 on the second inclined surface S2. The first angle θ-1 and the second angle θ-2 may be larger than the predetermined angle θ-P of the comparative example, facilitating the formation of the conductive layer CDL. A detailed description of the formation process of the conductive layer CDL will be provided later.

Referring to FIG. 2, the first opening OP1 may serve as a passage for allowing one of the circuit electrodes SD1, SD2 of the transistor TFT to be connected with the pixel electrode PE.

According to an embodiment of the present disclosure, the first opening OP1 may overlap the light-emitting region EA. The first opening OP1 may overlap (below) the light-emitting region EA to maximize the area of the light-emitting region EA. A detailed description of this will be provided later.

According to an embodiment of the present disclosure, the second opening OP2 may be defined on the second inclined surface S2, and the second opening OP2 may cover the light-emitting region EA in a plan view. In an embodiment, the second opening OP2 may have a larger area than the light-emitting region EA and may also have a larger area than the first opening OP1.

The flat layer PL may fill the first opening OP1 and the second opening OP2. For example, the flat layer PL may be disposed in the region between the pixel electrode PE and the conductive layer CDL. Since the second opening OP2 has a larger area than the light-emitting region EA, the flat layer PL filled in the second opening OP2 may cover the light-emitting region EA in a plan view.

In the present disclosure, the area of an opening may refer to the area defined at the topmost part of the inclined surface in the third direction DR3 in which the opening is defined.

The conductive layer CDL may be disposed on one of the circuit electrodes SD1, SD2 and on the inclined insulating layer SL. The conductive layer CDL may electrically connect one of the circuit electrodes SD1, SD2 to the pixel electrode PE. In an embodiment, the conductive layer CDL may be directly disposed on the first inclined surface S1 and the second inclined surface S2 of the inclined insulating layer SL.

In an embodiment, the conductive layer CDL may include a first flat portion F1, a second flat portion F2, and a third flat portion F3. The first flat portion F1 may be in direct contact with one of the circuit electrodes SD1, SD2 in the first opening OP1. The second flat portion F2 may be disposed between the inclined insulating layer SL and the flat layer PL and may be in contact with both the inclined insulating layer SL and the flat layer PL. The third flat portion F3 may be disposed between the inclined insulating layer SL and the pixel electrode PE and may be in direct contact with the pixel electrode PE.

In an embodiment, the third flat portion F3 may overlap the pixel defining layer PDL while not overlapping with the light-emitting region EA. In an embodiment, a first distance H1 between the first flat portion F1 and the substrate SS may be smaller than a second distance H2 between the second flat portion F2 and the substrate SS. In an embodiment, a third distance H3 between the third flat portion F3 and the substrate SS may be greater than the second distance H2. In an embodiment, an upper surface of the third flat portion F3 and an upper surface of the flat layer PL may be substantially flush with each other, which is to say, the upper surface of the third flat portion F3 and an upper surface of the flat layer PL have substantially the same height with respect to the substrate.

In an embodiment, the conductive layer CDL may be a single uninterrupted structure. In an embodiment, the conductive layer CDL may be formed of a transparent conductive oxide (TCO).

In an embodiment, according to the method for manufacturing a display device, which will be described later, the pixel electrode PE and the conductive layer CDL may be formed by simultaneously etching a preliminary pixel electrode PPE and a preliminary conductive layer PCDL in a single process. A single process may refer to a series of operations in which multiple components are formed at once through the same processing step.

In the above-described embodiment, as the pixel electrode PE and the conductive layer CDL are formed through a single process, one side PE-E of the pixel electrode PE in the first direction DR1 and one side CDL-E of the conductive layer CDL in the first direction DR1 may overlap each other in a plan view.

However, the embodiment is not necessarily limited thereto. In another embodiment, if the processes for forming the pixel electrode PE and the conductive layer CDL are performed in separate steps, one side of the pixel electrode PE in the first direction DR1 and one side of the conductive layer CDL in the first direction DR1 may be spaced apart from each other.

In an embodiment of the present disclosure, the flat layer PL may be disposed beneath the pixel electrode PE, which overlaps the light-emitting region EA.

The display device of a comparative example includes the light-emitting region and the pixel electrode. A lower surface of the pixel electrode, which overlaps the light-emitting region, is in contact with two different layers. In such a case, differences in the detailed shapes of the different underlying layers cause non-uniform light emission in the light-emitting region.

In the display device DD, according to an embodiment of the present disclosure, the lower surface of the pixel electrode PE, which overlaps the light-emitting region EA, is in contact only with the flat layer PL and not with any other components. Accordingly, the display device DD may achieve uniform light emission across the entire area of the light-emitting region EA and thus may improve the display quality of the display device DD.

In an embodiment, the flat layer PL may include an inorganic material. In an embodiment, the flat layer PL may include an organic material. In an embodiment, the flat layer PL may include a conductive material.

In an embodiment, the flat layer PL may include an inorganic material, and each pixel PX may have a different thickness of the flat layer PL. In this embodiment, the conductive layer CDL may be provided as a reflective film configured to reflect at least a portion of light, and the pixel electrode PE may be provided as a semi-transparent or transparent film configured to transmit at least a portion of light. The thicknesses of the flat layers PL arranged in each pixel may differ for each pixel to allow light emitted from each pixel to resonate.

In an embodiment, the flat layer PL may include an organic material and may further include a light-scattering element configured to scatter light. In this embodiment, the conductive layer CDL may be provided as a reflective film configured to reflect at least a portion of light, and the pixel electrode PE may be provided as a semi-transparent or transparent film configured to transmit at least a portion of light. The light emitted from each pixel may have a wider emission angle, and the side-view visibility of the display device may be improved.

Thus, embodiments may improve upon prior display designs by using two separated inclined surfaces to form more stable angles for a conductive layer, which connects the transistor and pixel electrode through defined openings. A flat layer beneath the pixel electrode ensures uniform contact and consistent light emission across the entire light-emitting region, enhancing display quality, while also enabling efficient, single-step manufacturing of the conductive and pixel layers.

FIG. 5 is a cross-sectional view illustrating a part of a display device DDa according to an embodiment. Referring to FIG. 5, in an embodiment, an inclined insulating layer SLa may include a first inclined surface S1a, a second inclined surface S2a, and a third inclined surface S3a. A first opening OP1a may be defined in the first inclined surface S1a, a second opening OP2a may be defined in the second inclined surface S2a, and a third opening OP3a may be defined in the third inclined surface S3a.

The area A3a of the third opening OP3a may be greater than the area A1a of the first opening OP1a. The area A2a of the second opening OP2a may be greater than the area A3a of the third opening Op3a.

Although the embodiment described with reference to FIG. 5 illustrates the inclined insulating layer SLa having three inclined surfaces S1a, S2a, S3a, the embodiment is not necessarily limited thereto. Depending on the embodiment, the number of inclined surfaces included in the inclined insulating layer may be adjusted to be at least two or more.

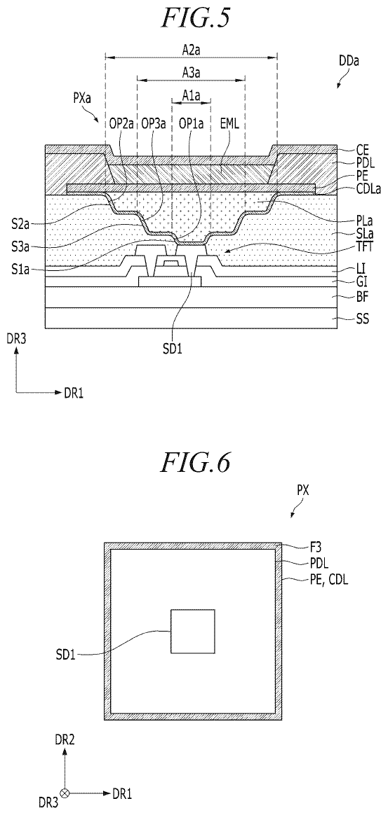

FIG. 6 is a plan view illustrating a certain pixel PX according to an embodiment. While FIG. 6 depicts the pixel electrode PE as having a rectangular shape, the present disclosure is not necessarily limited thereto. The pixel electrode PE may have various shapes, such as circular, elliptical, or polygonal.

Referring to FIG. 6, in an embodiment, the pixel electrode PE and the conductive layer CDL may be entirely overlapping in a plan view. The third flat portion F3 may be provided along an outer shape of the pixel electrode PE and may be in contact with the pixel electrode PE. In a plan view, the third flat portion F3 may have a closed-loop/frame shape. FIG. 6 exemplarily illustrates the third flat portion F3 as having a rectangular ring shape. However, the embodiment is not necessarily limited thereto, and the pixel electrode and the conductive layer may be only partially overlapping in a plan view.

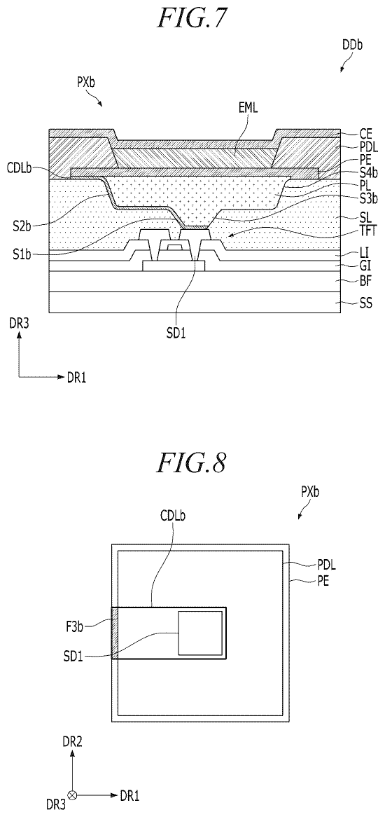

FIG. 7 is a cross-sectional view illustrating a part of a display device DDb according to an embodiment. FIG. 8 is a plan view illustrating a pixel PXb according to an embodiment.

Referring to FIG. 7, in an embodiment, a conductive layer CDLb may be disposed on at least a portion of inclined surfaces S1b, S2b, S3b, S4b of an inclined insulating layer SL. For example, the conductive layer CDLb may be disposed on the first inclined surface S1b and the second inclined surface S2b but may not be disposed on the third inclined surface S3b and the fourth inclined surface S4b.

Referring to FIG. 8, the conductive layer CDLb may extend to one side in the first direction DR1 and may partially overlap a pixel electrode PE in a plan view. A third flat portion F3b of the conductive layer CDLb, which is in contact with the pixel electrode PE, may extend along the second direction DR2 at one side of the pixel PXb.

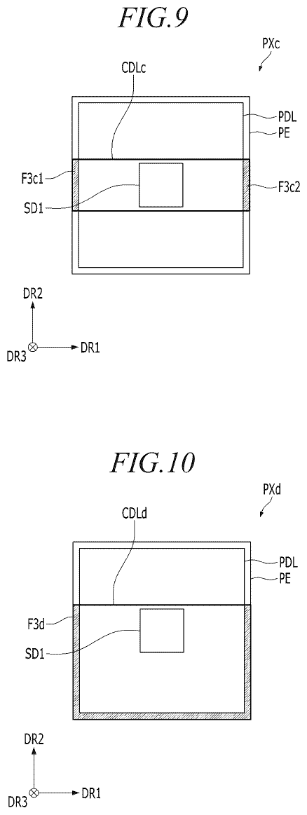

FIG. 9 is a plan view illustrating a pixel PXc according to an embodiment. FIG. 10 is a plan view illustrating a pixel PXd according to an embodiment.

Referring to FIG. 9, in an embodiment, a conductive layer CDLc may extend to both sides in the first direction DR1 and may partially overlap a pixel electrode PE in a plan view. A third flat portion F3c1, F3c2 may include a first sub-flat portion F3c1 and a second sub-flat portion F3c2, which are spaced apart from each other with a flat layer interposed therebetween. The conductive layer CDLc may be in contact with portions of both ends of the pixel electrode PE via the first sub-flat portion F3c1 and the second sub-flat portion F3c2.

Referring to FIG. 10, in an embodiment, a conductive layer CDLd may extend in both the first direction DR1 and the second direction DR2, and a third flat portion F3d may partially overlap an edge of a pixel electrode PE in a plan view. For example, in FIG. 10, the third flat portion F3d may be in contact with one side of the rectangular pixel electrode PE and with portions of sides extending from the ends of the one side.

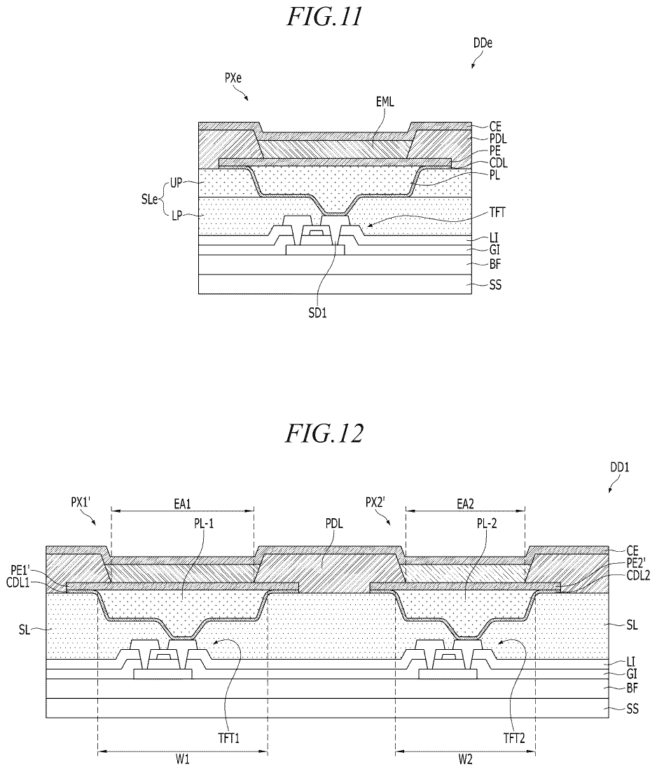

FIG. 11 is a cross-sectional view illustrating a part of a display device DDe according to an embodiment. Referring to FIG. 11, an inclined insulating layer SLe according to an embodiment may include a lower layer LP and an upper layer UP. The lower layer LP may include an inorganic material, and the upper layer UP may include an organic material. The lower layer LP may have a first opening OP1 defined therein that exposes a circuit electrode SD1. The first opening OP1 may be finely formed using a dry etching process, and the lower layer LP may include an inorganic material in order to facilitate the dry etching process.

FIG. 12 is a cross-sectional view illustrating a part of a display device DD1 according to an embodiment. Referring to FIG. 12, in an embodiment, a first light-emitting region EA1 of a first pixel PX1′ may have a width different from that of a second light-emitting region EA2 of a second pixel PX2′. In a cross-sectional view, a first light-emitting region EA1 may have a greater width than a second light-emitting region EA2. The width W1 of a flat layer PL-1 of the first pixel PX1′ may be greater than the width W2 of a flat layer PL-2 of the second pixel PX2′.

Pixels PX may each have a different light-emitting efficiency depending on its corresponding light-emitting diode. For example, a pixel corresponding to a light-emitting diode configured to emit blue light may have a lower device efficiency compared to a pixel corresponding to a light-emitting diode configured to emit green light. Alternatively, the visibility perceived by a user may differ depending on the wavelength of the light emitted from each pixel PX.

Accordingly, each of the light-emitting regions EA1, EA2 of the pixels PX may have a different width, and consequently, the widths of the flat layers PL-1, PL-2 may also be different. The display device DD may be configured to provide uniform light-emitting efficiency across the pixels PX or to provide uniform perceived visibility to the user, thereby improving the display quality of the display device DD.

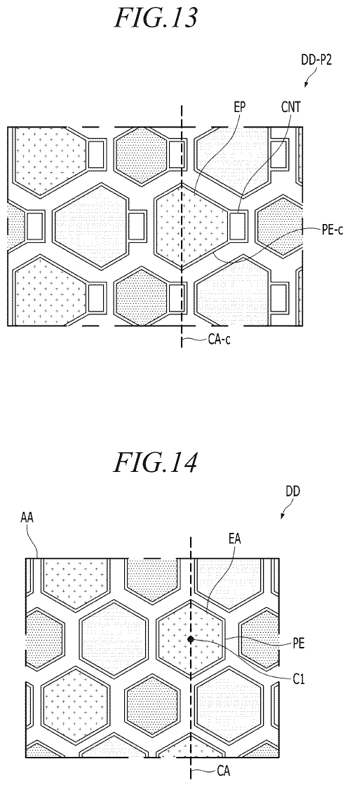

FIG. 13 is a plan view illustrating a part of a display device of a comparative example. FIG. 14 is a plan view illustrating a part of a display device according to an embodiment of the present disclosure.

Referring to FIG. 13, in a comparative example display device DD-P2, a pixel electrode PE-c overlaps both a light-emitting portion EP, where light is emitted, and a contact portion CNT, which electrically connects the pixel electrode to a transistor. Since the comparative example display device DD-P2 includes the contact portion CNT, which is substantially not a light-emitting area, it is limited in expanding the area of the light-emitting portion EP, which corresponds to the actual light-emitting region. In an embodiment, the pixel electrode PE-c may be asymmetric about a virtual central axis CA-c passing through the pixel electrode PE-c in a plan view.

In embodiments of the present disclosure, the display device DD may be applied to a virtual reality (VR) device, where a higher pixel per inch (PPI) may be required compared to the comparative example display device. To achieve improved resolution and device efficiency, the display device DD may require a light-emitting region EA that is as large as possible.

Referring to FIG. 14, the display device DD, in accordance with an embodiment of the present disclosure, may have the pixel electrode PE (shown in FIG. 2) and the transistor TFT (shown FIG. 2) electrically connected via the conductive layer CDL (shown in FIG. 2). The conductive layer CDL and the transistor TFT may be in contact with each other underneath a region overlapping the light-emitting region EA. Accordingly, the display device DD does not require the contact portion CNT (shown in FIG. 13) included in the comparative example display device DD-P2, and the pixel electrode PE may have a shape similar to the light-emitting region EA. The display device DD may achieve a larger light-emitting area compared to the comparative example display device DD-P2, thereby improving device efficiency and/or display quality.

In an embodiment, the display device DD may include an organic light-emitting diode and may have a larger light-emitting area. Moreover, the display device DD may achieve the same luminance as the comparative example display device DD-P2 even when driven at a lower current value. Accordingly, the light-emitting diode may have improved lifetime, thereby enhancing the reliability of the display device DD.

In embodiments, the pixel electrode PE may have a first center C1 defined therein. The first center C1 may be a geometric center, an incenter, a circumcenter, an excenter, or a centroid of the pixel electrode PE.

The pixel electrode PE may have a symmetric shape in a plan view about a virtual central axis CA passing through the first center C1. In an embodiment, the shortest distance from a boundary of the light-emitting region EA to a boundary of the pixel electrode PE may be uniform in a plan view in the first direction DR1 or the second direction DR2.

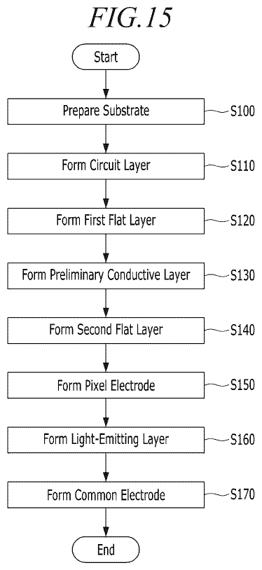

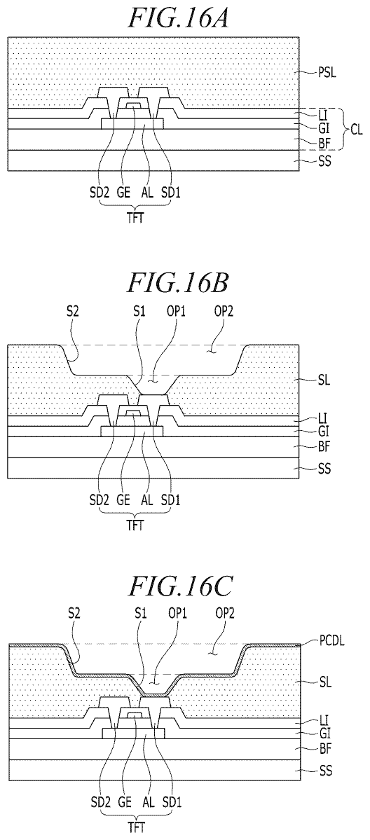

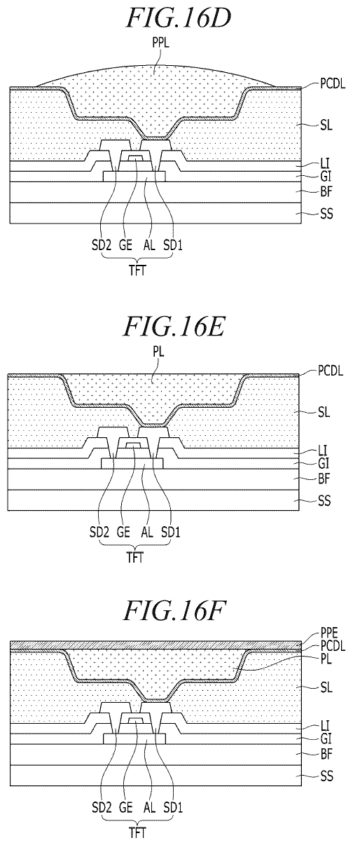

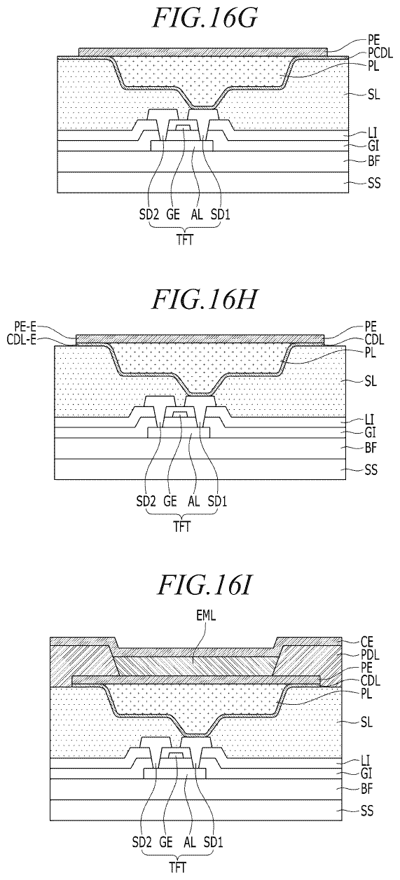

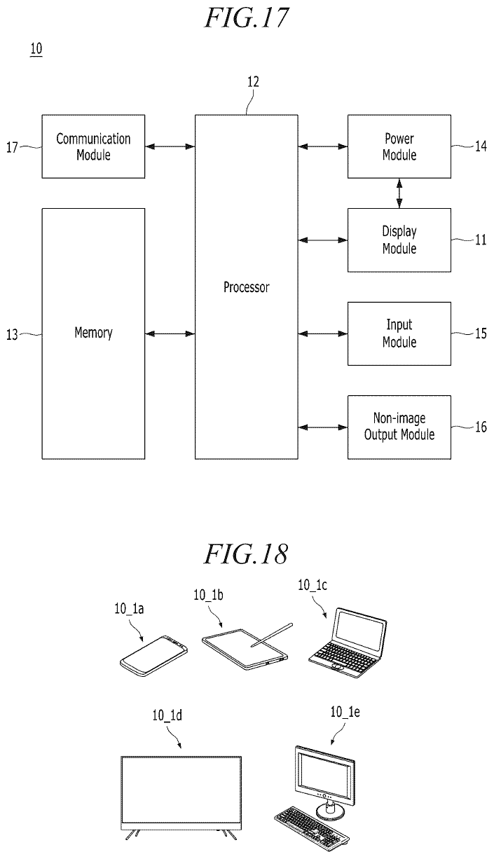

FIG. 15 is a flowchart illustrating a method for manufacturing a display device according to an embodiment. FIGS. 16A through 16I are cross-sectional views schematically illustrating respective manufacturing steps of the display device.

Referring to FIG. 15, a method for manufacturing a display device, according to an embodiment, may include preparing a substrate (S100), forming a circuit layer (S110), forming an inclined insulating layer (S120), forming a preliminary conductive layer (S130), forming a flat layer (S140), forming a pixel electrode (S150), forming a light-emitting layer (S160), and forming a common electrode (S170).

Referring to FIGS. 15 and 16A, in step S100, a substrate SS is prepared, and in step S110, a circuit layer CL may be formed on the substrate SS. The circuit layer CL may include a buffer layer BF, a transistor TFT, a gate insulating film GI, and an interlayer insulating film LI. The transistor TFT may include circuit electrodes SD1, SD2, an active layer AL, and a gate electrode GE.

In step S120, a first preliminary flat layer PSL may be formed on the circuit layer CL. Referring to FIG. 16B, the first preliminary flat layer PSL may then be patterned to form an inclined insulating layer SL. In the process of forming the inclined insulating layer SL, a halftone mask or a slit mask may be used. However, the embodiment is not necessarily limited thereto.

In embodiments, the inclined insulating layer SL may include a first inclined surface S1 and a second inclined surface S2. A first opening OP1 that exposes any one of the circuit electrodes SD1, SD2 may be defined in the first inclined surface S1. The second inclined surface S2 may be spaced apart from the first inclined surface S1 in the first direction DR1 and may be formed farther from the substrate SS than the first inclined surface S1 in the third direction DR3. A second opening OP2 may be defined in the second inclined surface S2.

Referring to FIGS. 15 and 16C, in step S130, a preliminary conductive layer PCDL may be formed. The preliminary conductive layer PCDL may be in contact with any one of the circuit electrodes SD1, SD2 at the first opening OP1 and may be directly disposed on the first inclined surface S1 and the second inclined surface S2.

Referring to FIGS. 15 and 16D, in step S140, a second preliminary flat layer PPL may be first formed at a location corresponding to the light-emitting region EA (see FIG. 2). In this embodiment, the second preliminary flat layer PPL may be patterned to correspond to the light-emitting region EA (see FIG. 2) to prevent a residual material from remaining over a wide area during the subsequent planarization of a second preliminary flat layer PPL. However, the embodiment is not necessarily limited thereto, and in other embodiments, the second preliminary flat layer (not shown) may be deposited across the entire surface.

Referring to FIGS. 16D and 16E, the second preliminary flat layer PPL may be planarized to form a flat layer PL. The planarization process may be performed using, but not necessarily limited to, a chemical mechanical planarization (CMP) process or a dry etching process.

Referring to FIGS. 15 and 16F, in step S150, a preliminary pixel electrode PPE may be formed on the flat layer PL and the preliminary conductive layer PCDL. Referring to FIG. 16G, a portion of the preliminary pixel electrode PPE may then be removed to form a pixel electrode PE corresponding to the light-emitting region EA (see FIG. 2). Referring to FIG. 16H, a portion of the preliminary conductive layer PCDL may then be removed to form a conductive layer CDL corresponding to the light-emitting region EA (see FIG. 2).

In an embodiment, the step of forming the pixel electrode PE and the step of forming the conductive layer CDL may be performed as separate processes. However, the embodiment is not necessarily limited thereto, and in other embodiments, the pixel electrode PE and the conductive layer CDL may be formed simultaneously in a single process. For example, the preliminary conductive layer PCDL (see FIG. 16F) and the preliminary pixel electrode PPE (see FIG. 16F) may be etched together in a same single process to form the conductive layer CDL (see FIG. 16H) and the pixel electrode PE (see FIG. 16H).

In this embodiment, to allow the preliminary conductive layer PCDL (see FIG. 16F) to be etched in the same process as the preliminary pixel electrode PPE, the preliminary conductive layer PCDL (see FIG. 16F) may include a transparent conductive oxide (TCO), and the etching process may be a wet etching process.

Referring to FIGS. 15 and 16I, a pixel defining layer PDL may then be formed on the pixel electrode PE and the inclined insulating layer SL, and in step S160, a light-emitting layer EML may be formed between the pixel defining layers PDL. Then, in step S170, a common electrode CE may be formed on the light-emitting layer EML and the pixel defining layer PDL.

Thus, the method for manufacturing the display device involves sequentially forming a substrate, circuit layer, inclined insulating layer with openings, conductive and flat layers, and then etching to create the pixel electrode and conductive layer (either separately or in a single process). The process may then add a light-emitting layer and a common electrode, resulting in a structured display optimized for performance and manufacturability.

With the method for manufacturing a display device according to an embodiment of the present disclosure, the inclined insulating layer SL may be formed to include at least two inclined surfaces, and the conductive layer CDL may be formed on the inclined insulating layer SL. The conductive layer CDL may be in contact with any one of the circuit electrodes SD1, SD2 through the first opening OP1 and may also be in contact with the pixel electrode PE. The pixel electrode PE and the transistor TFT may be electrically connected to each other via the conductive layer CDL. As the inclined insulating layer SL is formed to include at least two inclined surfaces, the conductive layer CDL may be formed in a stable fashion, thereby improving the reliability of the display device DD. Also, as the inclined insulating layer SL is formed to have at least two inclined surfaces, only one of the circuit electrodes SD1, SD2 may be exposed, thereby further enhancing the reliability of the display device DD.

As the flat layer PL is disposed beneath the pixel electrode PE overlapping the light-emitting region EA (see FIG. 2), the display device DD may achieve uniform light emission across the entire light-emitting region EA, thereby improving the display quality of the display device DD.

The display device according to embodiments of the present disclosure may be applied to various electronic devices. An electronic device according to an embodiment may include the above-described display device and may further include other modules or components in addition to the display device that provide additional functionalities.

FIG. 17 is a block diagram of an electronic device according to an embodiment. Referring to FIG. 17, an electronic device 10, according to an embodiment, may include a display module 11, a processor 12, a memory 13, and a power module 14. The electronic device 10 may further include an input module 15, a non-image output module 16, and/or a communication module 17.

The electronic device 10 may be configured to output various types of information in the form of images via the display module 11. Once the processor 12 executes an application stored in the memory 13, the display module 11 may be configured to provide image information associated with the application to a user. The power module 14 may include a power supply module, such as a power adapter or a battery device, and a power conversion module configured to convert the power supplied by the power supply module into a form necessary for operating the electronic device 10. The input module 15 may be configured to provide input information to the processor 12 and/or the display module 11. The non-image output module 16 may be configured to receive information other than image data from the processor 12, such as audio, haptic feedback, and/or light emission, and may provide such information to the user. The communication module 17 may be configured to transmit and receive information between the electronic device 10 and an external device and may include a receiver and a transmitter.

At least one of the above-described components of the electronic device 10 may be included within the display device according to the aforementioned embodiments. Additionally, some of the individual modules functionally included within a single module may be integrated into the display device, while others may be provided separately from the display device. For example, the display device may include the display module 11, while the processor 12, the memory 13, and the power module 14 may be provided as components of the electronic device 10 rather than being part of the display device.

FIGS. 18 to 20 are schematic views illustrating electronic devices according to various embodiments. FIGS. 18 to 20 illustrate various examples of electronic devices to which the display device according to embodiments may be applied.

FIG. 18 illustrates examples of electronic devices, including a smartphone 10_1a, a tablet computer 10_1b, a laptop/notebook computer 10_1c, a TV 10_1d, and a computer monitor 10_1e.

The smartphone 10_1a may include an input module, such as a touch sensor, as well as a communication module, in addition to a display module 11. The smartphone 10_1a may be configured to process information received via the communication module or other input modules and display the processed information through the display module of the display device.

The tablet computer 10_1b, the laptop/notebook computer 10_1c, TV 10_1d, and the computer monitor 10_1e may include a display module and an input module, and may further include a communication module depending on the implementation.

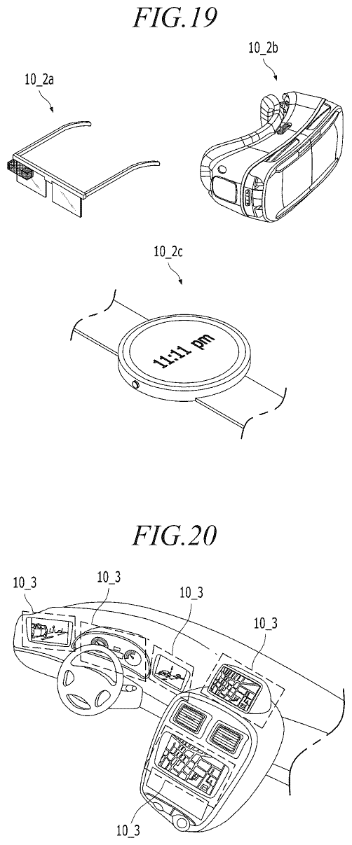

FIG. 19 illustrates examples in which an electronic device including a display module is applied to a wearable electronic device. Wearable electronic devices may include smart glasses 10_2a, a head-mounted display 10_2b, or a smartwatch 10_2c.

The smart glasses 10_2a and the head-mounted display 10_2b may each include a display module configured to output display images and a reflector configured to reflect the output display images to a user's eyes. Accordingly, the smart glasses 10_2a and the head-mounted display 10_2b may be configured to provide virtual reality (VR) or augmented reality (AR) images to the user.

The smartwatch 10_2c may include a biometric sensor as an input device, and the biometric sensor may be configured to detect biometric information, which may then be provided to the user through the display module.

FIG. 20 illustrates an example in which an electronic device including a display module is applied to a vehicle. For example, the electronic device 10_3 may be applied to a vehicle's instrument panel, center fascia, or a center information display (CID) disposed on the vehicle's dashboard. Additionally, the electronic device 10_3 may be applied to a rear-view mirror display configured to replace side rear-view mirrors.

Various embodiments of the present disclosure have been described above, but these are exemplary and are not necessarily intended to limit the present disclosure. Those skilled in the art to which the present disclosure pertains may make various modifications and changes to the embodiments by adding, changing, deleting, or adding certain elements, without departing from the scope of the technical ideas of the present disclosure, and such modifications and changes should also be regarded as being within the scope of the present disclosure.

What is claimed is:

1. A display device, comprising:
a substrate comprising a light-emitting region;
a transistor disposed on the substrate and comprising a circuit electrode;
an inclined insulating layer disposed on the transistor and comprising a first inclined surface in which a first opening is defined by and a second inclined surface in which a second opening is defined by;
a conductive layer disposed on the inclined insulating layer and the circuit electrode, the conductive layer directly contacting the circuit electrode through the first opening and electrically connected to the circuit electrode through the first opening;
a flat layer disposed on the conductive layer;
a pixel electrode disposed on the flat layer and the conductive layer, the pixel electrode directly contacting the flat layer and the conductive layer;
a light-emitting layer disposed on the pixel electrode; and
a common electrode disposed on the light-emitting layer,
wherein the first opening, the second opening, and the light-emitting region overlap each other in a plan view,
wherein the second opening has a larger area than each of the first opening and the light-emitting region, and
wherein the flat layer covers the light-emitting region in the plan view.

2. The display device of claim 1, wherein the pixel electrode covers the flat layer.

3. The display device of claim 1, wherein the conductive layer comprises a first contact portion in contact with the pixel electrode, and
wherein the first contact portion does not overlap the light-emitting region.

4. The display device of claim 3, wherein the conductive layer further comprises a second contact portion spaced apart from the first contact portion and contacting the pixel electrode, and
wherein the second contact portion does not overlap the light-emitting region.

5. The display device of claim 4, wherein the first contact portion and the second contact portion face each other with the flat layer interposed therebetween.

6. The display device of claim 1, wherein the conductive layer comprises first to third flat portions extending in parallel with the substrate,
wherein the first flat portion is in contact with the circuit electrode,
wherein the second flat portion is in contact with both the inclined insulating layer and the flat layer, and
wherein the third flat portion is in contact with both the inclined insulating layer and the pixel electrode.

7. The display device of claim 6, wherein a first distance between the first flat portion and the substrate is smaller than a second distance between the second flat portion and the substrate, and
wherein a third distance between the third flat portion and the substrate is greater than the second distance.

8. The display device of claim 6, wherein an upper surface of the third flat portion and an upper surface of the flat layer have substantially a same height with respect to the substrate.

9. The display device of claim 1, wherein the conductive layer is a single uninterrupted structure.

10. The display device of claim 1, wherein one side of the conductive layer and one side of the pixel electrode overlap each other in the plan view.

11. The display device of claim 1, wherein one side of the conductive layer and one side of the pixel electrode are spaced apart from each other.

12. The display device of claim 1, wherein the inclined insulating layer further comprises at least one inorganic layer and at least one organic layer.

13. The display device of claim 1, wherein the inclined insulating layer further comprises a third inclined surface in which a third opening is defined,
wherein the third opening and the first opening overlap each other in the plan view, and
wherein the third opening has a larger area than the first opening and a smaller area than the second opening.

14. The display device of claim 1, wherein the pixel electrode has a symmetrical shape about a central axis extending through the pixel electrode in the plan view.

15. A method for manufacturing a display device, the method comprising:
preparing a substrate having a light-emitting region defined therein;
forming a circuit layer on the substrate, the circuit layer comprising a transistor;
forming an inclined insulating layer on the circuit layer, the inclined insulating layer comprising a first inclined surface in which a first opening is defined and a second inclined surface in which a second opening is defined;
forming a preliminary conductive layer on the inclined insulating layer;
forming a flat layer on the preliminary conductive layer;
forming a conductive layer and a pixel electrode on the flat layer;
forming a light-emitting layer on the pixel electrode; and
forming a common electrode on the light-emitting layer,
wherein the pixel electrode and the conductive layer are electrically connected to each other,
wherein the conductive layer and the transistor are electrically connected to each other through the first opening,
wherein the second opening has a larger area than each of the first opening and the light-emitting region, and
wherein the flat layer covers the light-emitting region.

16. The method of claim 15, wherein forming the flat layer comprises:
patterning a second preliminary flat layer on the conductive layer, overlapping the light-emitting region; and
planarizing the second preliminary flat layer to form the flat layer.

17. The method of claim 16, wherein the pixel electrode covers the flat layer.

18. The method of claim 15, wherein forming the conductive layer and the pixel electrode comprises:
forming a preliminary pixel electrode on the flat layer and the conductive layer; and
etching the preliminary pixel electrode and the preliminary conductive layer,
wherein the etching of both the preliminary pixel electrode and the preliminary conductive layer is performed in a single process.

19. An electronic device comprising a display device, the display device comprising:
a substrate comprising a light-emitting region;
a transistor disposed on the substrate and comprising a circuit electrode;
an inclined insulating layer disposed on the transistor and comprising a first inclined surface in which a first opening is defined and a second inclined surface in which a second opening is defined;
a conductive layer disposed on the inclined insulating layer and the circuit electrode, the conductive layer directly contacting the circuit electrode through the first opening and electrically connected to the circuit electrode through the first opening;
a flat layer disposed on the conductive layer;
a pixel electrode disposed on the flat layer and the conductive layer, the pixel electrode directly contacting the flat layer and the conductive layer;
a light-emitting layer disposed on the pixel electrode; and
a common electrode disposed on the light-emitting layer,
wherein the first opening, the second opening, and the light-emitting region overlap each other in a plan view,
wherein the second opening has a larger area than each of the first opening and the light-emitting region, and
wherein the flat layer covers the light-emitting region in the plan view.

20. The electronic device of claim 19, further comprising:
a processor configured to control the display device;
a memory storing data for operating the display device or the processor stored therein; and
power conversion module configured to generate or supply power.
